(19) United States
(12) Patent Application Publication
(10) Pub. No.: US 2009/0177410 A1
(43) Pub. Date: Jul. 9, 2009

(54) REAL-TIME MONITORING DEVICE AND OPERATION METHOD THEREOF

(75) Inventor: Mamoru KONISHI, Miyagi (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: OKI SEMICONDUCTOR CO., LTD., Tokyo (JP)

(21) Appl. No.: 12/339,130

(22) Filed: Dec. 19, 2008

(30) Foreign Application Priority Data
Jan. 8, 2008 (JP) 2008-001596

(51) Int. Cl. G01N 31/00; G01R 19/00; G01R 21/00; H03M 1/00

(52) U.S. Cl. 702/22; 702/64; 702/60; 702/57

(57) ABSTRACT

A real-time monitoring device includes a microcomputer, a conductor, and a capacitor. The microcomputer monitors changes during plasma processing in a potential of a semiconductor wafer surface that are read by a sensor. The conductor is disposed in a vicinity of the microcomputer. The capacitor connects the conductor and a power supply connection terminal of the microcomputer.

### CROSS-REFERENCE TO RELATED APPLICATION

This application claims priority under 35 USC 119 from Japanese Patent Application No. 2008-001596, the disclosure of which is incorporated by reference herein.

### BACKGROUND OF THE INVENTION

1. Field of the Invention

The present invention relates to a real-time monitoring device and operation method thereof, and in particular, relates to, in a semiconductor fabricating process, the control of the collecting, storing and transmitting of physical amounts that are generated at a plasma processing device.

2. Description of the Related Art

In order to simplify plasma processing that is used in a semiconductor fabricating process and to fabricate a semiconductor with high precision, it is very important to maintain high quality and high yield of high-performance semiconductors.

Thus, there has been proposed a method of transmitting the change in the potential or current of a self bias voltage Vdc or the like, that is generated during surface treatment of a semiconductor that uses plasma, to the exterior of a plasma chamber as a signal expressing the change in the light emitting intensity of a light emitting element (refer to Japanese Patent Application Laid-Open (JP-A) No. 2002-100617).

Further, a structure has been proposed that enables online monitoring (observation, measurement, or supervision) at the position of a substrate (wafer) that is an object of processing, in the surface treatment of a semiconductor that uses plasma (refer to JP-A No. 2003-282546).

There has also been proposed a structure in which, by forming an electromagnetic shielding layer at the surface or at the interior of a resin for circuit protection that is injected into an electronic device, can prevent malfunctioning of the electronic device in a high frequency electric field, and can reduce the costs low (refer to JP-A No. 07-263888).

However, at the time of surface treatment of a semiconductor that uses plasma, there are cases in which, depending on the resolution of the change in the light emitting intensity of the light emitting element on the wafer, it is difficult to differentiate between normal values and abnormal values. Further, it is difficult to quantitatively grasp sudden changes in the transient state during the several seconds immediately after plasma generation. In more detail, generally, a light emitting diode carries out operation in the range of from about 0V to 5V, but does not emit light at less than or equal to forward drop voltage (approximately 2V). For example, in the case of a plasma condition in which the self bias voltage Vdc changes from 0V to 500V, in order to operate a light emitting diode by using the self bias voltage Vdc, the self bias voltage Vdc must be supplied to the light emitting diode after being reduced by about 1/100. In this case, if the self bias voltage Vdc is from 0V to less than or equal to about 200V, there is the possibility that data cannot be transferred because the light emitting element does not emit light normally. Even in cases in which the light emitting element does emit light, it is presumed that there will be a very weak change in light emitting intensity, and therefore, accurate and highly-reproducible measurement is difficult.

Because the change in the light emitting intensity of the light emitting element is used as a signal, this technique cannot be applied in a plasma chamber in which the signal light path cannot be provided appropriately. This shows that the light that is the signal cannot be observed, for example, in cases in which there is no observation window at the plasma chamber, or in cases in which, at the time of the wafer processing, the stage on which the wafer is located is moved for plasma processing and can no longer be viewed from the observation window, or the like.

Further, a high frequency electric field (magnetic field) is generated in the space within the plasma chamber where high frequency plasma typified by 13.56 MHz is generated, and the electronic circuit does not operate normally. Therefore, in order to operate an, electronic circuit in a high frequency electric field, there is a method of coating the surface thereof with a particular resin material. However, if the entire electronic circuit, including the power supply, is coated with a particular resin material, it is difficult to replace worn members or broken-down parts such as the power supply or the like.

The plasma parameters, such as the self bias voltage Vdc and the like, are affected by the amount of the secondary electrons that are supplied from the material that is exposed to the plasma, and by the types of and the generated amounts of reaction products generated by the reaction with this material. There is the possibility that, by using a particular resin material that is not used in a semiconductor fabricating device, a plasma, that is different than the plasma used in the semiconductor manufacturing process, will become the object of measurement.

### SUMMARY OF THE INVENTION

The present invention has been made in view of the above circumstances and provides a real-time monitoring device and operation method thereof that can stably collect plasma parameters from immediately after plasma generation and outputted data of a sensor that measures the potential of a processed wafer surface, and can and store them in a memory and transfer them to the exterior of a plasma chamber.

A first aspect of the present invention provides a real-time monitoring device including, a microcomputer that monitors changes during plasma processing in a potential of a semiconductor wafer surface that are read by a sensor, a conductor disposed in a vicinity of the microcomputer, and a capacitor that connects the conductor and a power supply connection terminal of the microcomputer.

A second aspect of the present invention provides a real-time monitoring device including, a microcomputer that collects sensor outputs of sensors that are disposed at respective locations within a semiconductor fabricating device and that, in a plasma process used in a semiconductor fabricating process, sense and measure at least one of plasma parameters including self bias voltage, a potential of a plasma processed wafer surface, or a potential generated within a fine pattern, and a conductor disposed in a vicinity of a circuit whose main body is the microcomputer and that comprises a plurality of electronic parts. The conductor and a power supply connection terminal of the microcomputer are connected via a capacitor, the microcomputer being part of a microcomputer circuit that controls a monitoring operation of sensor outputs in the plasma process.

A third aspect of the present invention provides a real-time monitoring device including a microcomputer that monitors changes during plasma processing in a potential of a semiconductor wafer surface that are read by a sensor, and a connecting portion of a direct current power supply that is supplied to the microcomputer has a potential equal to a high frequency voltage induced by plasma.

A fourth aspect of the present invention provides a real-time monitoring device including, a microcomputer that collects sensor outputs of sensors that are disposed at respective locations within a semiconductor fabricating device and that, in a plasma process used in a semiconductor fabricating process, sense and measure at least one of plasma parameters including self bias voltage, a potential of a plasma processed wafer surface, or a potential generated within a fine pattern, and a conductor is disposed in a vicinity of a circuit whose main body is the microcomputer and that comprises a plurality of electronic parts, and a connecting portion of a direct current power supply supplied to the microcomputer is connected by a capacitor to the conductor, the microcomputer being part of a microcomputer circuit that controls a monitoring operation of sensor outputs in the plasma process, and the conductor having a potential equal to a high frequency voltage induced by plasma, when there is an unused terminal at the microcomputer, the unused terminal is directly connected to the conductor or is connected to a negative power supply portion via a resistor, and operationally unstable signal transmitting and receiving operations caused by a high frequency electric field of the microcomputer circuit are stabilized.

A fifth aspect of the present invention provides a control method for measuring a potential used in a microcomputer circuit in a real-time monitoring device, the real-time monitoring device including, a microcomputer that collects sensor outputs of sensors that are disposed at respective locations within a semiconductor fabricating device and that, in a plasma process used in a semiconductor fabricating process, sense and measure at least one of plasma parameters including self bias voltage, a potential of a plasma processed wafer surface, or a potential generated within a fine pattern, and a conductor disposed in a vicinity of a circuit whose main body is the microcomputer and that comprises a plurality of electronic parts, where the conductor and a power supply connection terminal of the microcomputer are connected via a capacitor, the microcomputer being part of a microcomputer circuit that controls a monitoring operation of sensor outputs in the plasma process, and the method including, inputting the sensor outputs, performing AD conversion that converts the sensor outputs from analog signals into digital signals, storing measurement data corresponding to digital signals of the AD-converted sensor outputs, and in accordance with a specific signal, performing IR transmission that transmits, by infrared rays, the stored measurement data.

A sixth aspect of the present invention provides a real-time monitoring device that collects sensor outputs of sensors that are disposed at respective locations within a semiconductor fabricating device and that, in a plasma process used in a semiconductor fabricating process, sense and measure at least one of plasma parameters including self bias voltage, a potential of a plasma processed wafer surface, or a potential generated within a fine pattern, the real-time monitoring device comprising, a microcomputer, a power supply section, a capacitor, an infrared ray receiving unit, and an infrared ray transmitting unit, a microcomputer circuit in which a conductor is disposed in a vicinity of the microcomputer, a control signal transmitting section that transmits a control signal generated by infrared rays for controlling the microcomputer circuit, such that the control signal is received by the infrared ray receiving unit, a sensor output receiving section that receives, from the infrared ray receiving unit, the sensor outputs from the infrared ray transmitting unit of the microcomputer circuit, and an analyzing section that analyzes the sensor outputs received by the sensor output receiving section. On the basis of the control signal from the control signal transmitting section, the microcomputer circuit acquires the sensor outputs, and stores the acquired sensor outputs temporarily in a sensor output storing section, and, on the basis of the control signal from the control signal transmitting section, the microcomputer circuit transmits the sensor outputs by using the infrared ray transmitting unit.

A seventh aspect of the present invention provides a real-time monitoring device including, a microcomputer that collects sensor outputs of sensors that are disposed at respective locations within a semiconductor fabricating device and that, in a plasma process used in a semiconductor fabricating process, sense and measure at least one of plasma parameters including self bias voltage, a potential of a plasma processed wafer surface, or a potential generated within a fine pattern, and a conductor disposed in a vicinity of a circuit whose main body is the microcomputer and that comprises a plurality of electronic parts. The conductor and a power supply connection terminal of the microcomputer are connected via a capacitor, the microcomputer being part of a microcomputer circuit that controls a monitoring operation of sensor outputs in the plasma process, and the microcomputer circuit includes an inputting section that inputs the sensor outputs, an AD converting section that performs AD conversion that converts the sensor outputs inputted by the inputting section from analog signals into digital signals, a storing section that stores measurement data corresponding to digital signals of the AD-converted sensor outputs by the AD converting section, an IR transmitting section that performs, in accordance with a specific signal, IR transmission that transmits, by infrared rays, the stored measurement data, and a control section that controls the inputting section, the AD converting section, the storing section and the IR transmitting section, the control section that executes the AD conversion, the storing of the AD-converted measurement data, and, in response to the specific signal, the IR transmission of the stored measurement data.

### BRIEF DESCRIPTION OF THE DRAWINGS

FIG. 1 is a circuit diagram of a microcomputer control device relating to a first exemplary embodiment;

FIG. 2 is a substrate sectional view of the microcomputer control device relating to the first exemplary embodiment;

FIG. 3 is a first block diagram of the microcomputer control device relating to the first exemplary embodiment;

FIG. 4 is a second block diagram of a microcomputer receiver of the microcomputer control device relating to the first exemplary embodiment;

FIG. 5 is a block diagram of a real-time monitoring device relating to a second exemplary embodiment;

FIG. 6 is a signal block diagram of a remote controller relating to the second exemplary embodiment;

FIG. 7 is a signal block diagram of a microcomputer transmitter relating to the second exemplary embodiment;

FIG. 8 is a signal block diagram of a microcomputer receiver, a USB interface and a PC relating to the second exemplary embodiment;

FIG. 9 is a first flowchart showing control of the remote controller relating to the second exemplary embodiment;

FIG. 10 is a second flowchart showing control of the microcomputer transmitter relating to the second exemplary embodiment; and

FIG. 11 is a third flowchart showing control of the microcomputer receiver relating to the second exemplary embodiment.

### DETAILED DESCRIPTION OF THE INVENTION

### First Exemplary Embodiment

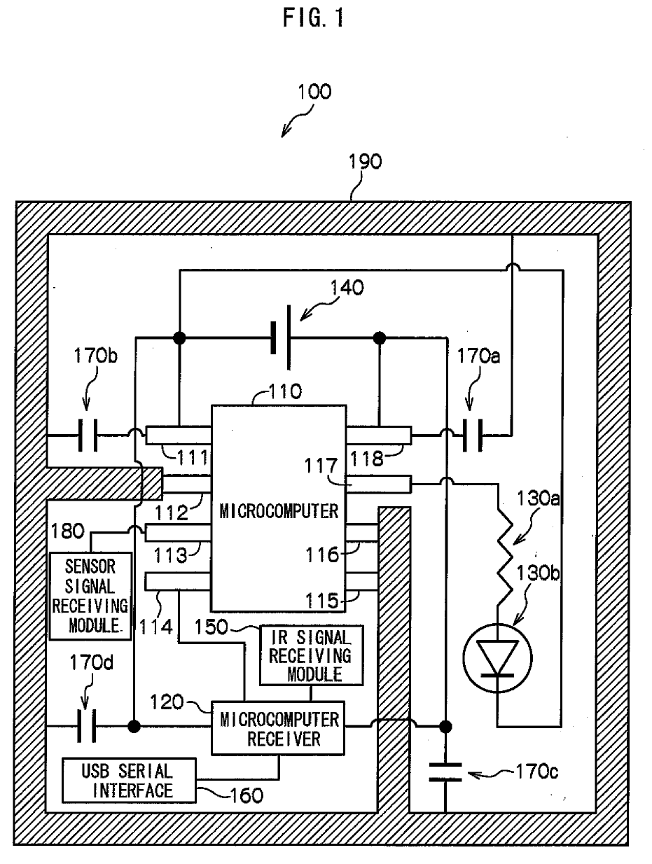

FIG. 1 is a circuit diagram of a microcomputer circuit 100 that includes a microcomputer 110 relating to a first exemplary embodiment.

The microcomputer circuit 100 is structured by the microcomputer 110, a microcomputer receiver 120, a resistor element 130a, an infrared light emitting diode (hereinafter called infrared LED) 130b, a power supplying section 140, an IR (InfraRed ray) signal receiving module 150, a USB (Universal Serial Bus) serial interface 160, capacitors 170a, 170b, 170c, 170d, a sensor signal receiving module 180, and a copper tape 190.

Note that the microcomputer 110 is an 8-pin-type IC (Integrated Circuit), and terminals for connection, that are a first pin 111, a second pin 112, a third pin 113, a fourth pin 114, a fifth pin 115, a sixth pin 116, a seventh pin 117 and an eighth pin 118, are set thereat. The copper tape 190 may be any type of form configuration and material provided that it is a conductor (a conductor plate), and, for example, aluminum tape or the like may be used. Further, the microcomputer 110 is a PIC (Peripheral Interface Controller: an IC for connection and control of peripheral devices).

At the microcomputer 110, the first pin 111 is connected to the negative side (the −side) of the power supplying section 140, and the eighth pin 118 is connected to the positive side (the +side) of the power supplying section 140. Further, at the microcomputer 110, the first pin 111 is connected to the copper tape 190 via the capacitor 170b, and the eighth pin 118 is connected to the copper tape 190 via the capacitor 170a. Moreover, at the microcomputer 110, the third pin 113 is connected to the sensor signal receiving module, the fourth pin 114 is connected to the microcomputer receiver 120, and the seventh pin 117 is connected is connected to one infrared LED circuit 130 to which the resistor element 130a and the infrared LED 130b are connected. Also at the microcomputer 110, the second pin 112, the fifth pin 115 and the sixth pin 116 are directly connected to the copper tape 190. Note that the other infrared LED circuit 130, that is structured by the resistor element 130a and the infrared LED 130b being connected, is connected to the negative side of the power supplying section 140.

The microcomputer receiver 120 is connected to the fourth pin 114 of the microcomputer 110 and the IR signal receiving module 150. The microcomputer receiver 120 is connected to the positive side of the power supplying section 140, and further, that wire (the wire connecting the microcomputer receiver 120 and the positive side of the power supplying section 140) is connected to the copper tape 190 via the capacitor 170c. The microcomputer receiver 120 is connected to the negative side of the power supplying section 140, and further, that wire (the wire connecting the microcomputer receiver 120 and the negative side of the power supplying section 140) is connected to the copper tape 190 via the capacitor 170d.

The microcomputer circuit 100 is a circuit in which, in accordance with a program stored in a memory 360 that is installed in the microcomputer 110, the infrared LED 130b flashes on-and-off in accordance with a signal pattern determined by a given cycle program.

The copper tape 190 is affixed to a vicinity of the outer periphery of the microcomputer 110. The copper tape 190 and both of the positive side and the negative side of the power supplying section 140 of the microcomputer 110 are connected via the capacitors 170a (the positive side), 170b (the positive side) of capacities of about 0.1 uF for example, such that the connecting portion of a DC power supply that is supplied to the microcomputer 110 is the same potential as high frequency voltage that is induced by the plasma.

A non-used terminal that is not used in operation of the microcomputer 110 of the first exemplary embodiment (hereinafter called the NC pin (Non Connection pin)) is directly connected to the copper tape 190. Note that the terminal of the NC pin and the copper tape 190 may be connected to the negative power supply side of the power supplying section 140 via a resistor element.

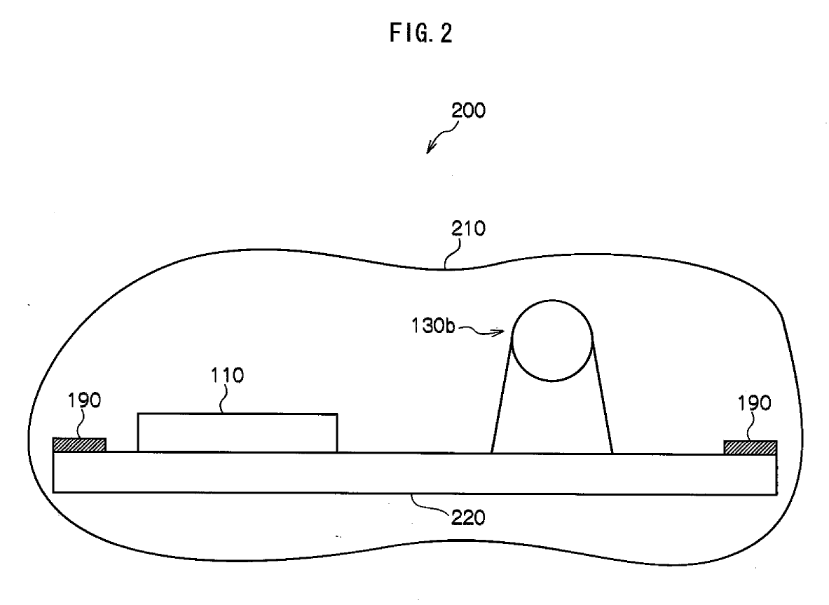

In order to ensure electrical insulation (cutting of the DC component) of the microcomputer circuit 100 that includes the microcomputer 110, the reverse surface side of the substrate forming the microcomputer circuit 100 (the soldering processing side) is covered by Kapton tape 210 (a polyimide tape for heat-resistance and insulation shown in FIG. 2).

A substrate sectional view 200 of the microcomputer circuit 100 relating to the first exemplary embodiment is shown in FIG. 2.

The substrate sectional view 200 shows a cross-sectional view of the substrate of the circuit diagram of the microcomputer circuit 100 shown in FIG. 1, and is structured by the microcomputer 110, the infrared LED 130b, the copper tape 190, a substrate 220 and the Kapton tape 210. Further, the substrate 220, on which the microcomputer 110, the infrared LED 130b and the copper tape 190 are outfitted, is covered by the Kapton tape 210.

At the substrate obverse side at which electronic parts such as the microcomputer 110 and the like are disposed, a single-layer covering of the Kapton tape 210 is provided, in the same way as at the reverse, in order to prevent flowing of charged particles such as ions and the like from the plasma, and reactive radicals and reaction products. Note that, although the Kapton tape 210 is used here, it is better to use a thin sheet or tape of a Teflon™ material that is used in semiconductor fabricating devices.

The microcomputer circuit 100 is set within a plasma chamber (not shown) of a semiconductor fabricating device, and a high frequency plasma is generated. At this time, a high frequency electric field, that is caused by the high frequency power supply frequency for generating the high frequency plasma, acts on the space within the plasma chamber and maintains the plasma, and simultaneously, the microcomputer circuit 100 as well is exposed to this high frequency electric field. Therefore, high frequency electromotive force arises at the microcomputer 110, the copper tape 190 at the periphery of the microcomputer 110, and the conductors included in the microcomputer circuit 100. The magnitude of the high frequency electromotive force that is generated differs in accordance with the magnetic characteristics such as the permeability and the like of the material. Therefore, a difference arises in the magnitude of the high frequency electromotive force that is generated within the microcomputer circuit 100 that is structured by plural electrically-conductive materials, and a potential difference of the high frequency electromotive force arises. High frequency current flows within the microcomputer circuit 100 in accordance with this potential difference.

In accordance with the structure of the present invention, the high frequency electromotive force, that is generated in a vicinity of the microcomputer circuit 100, arises at the copper tape 190. Due to this electromotive force being connected to both the positive side and the negative side of the power supplying section 140 of the microcomputer 110 via the capacitors 170a (the positive side), 170b (the negative side), the interior of the microcomputer circuit 100 and the high frequency electromotive force generated at the copper tape 190 become the same potential. Note that, at this time, the positive side capacitor 170a and the negative side capacitor 170b become bypass capacitors, and function to remove the DC component and transmit only the AC component (be conductive in terms of high frequency), and therefore, the high frequency electromotive force becomes equal.

Note that, the greater the surface area of the copper tape 190 that is a conductor (conductor plate) disposed at the periphery of the vicinity of the microcomputer circuit 100, the larger the generated high frequency electromotive force can be made to be. Therefore, it is preferable to make the surface area as large as possible. If the conductor surface area is made to be large, the impedance becomes small, and due thereto, the impedance of the conductor overall becomes small. Therefore, when a difference arises in the magnitude of the high frequency electromotive force, the induced high frequency current flows at the conductor side where the impedance is small. Further, at the microcomputer 110 of the microcomputer circuit 100, there are NC pins that are terminals of the microcomputer 110 that are not used in terms of the specifications, and these NC pins are treated such that they are fixed to a predetermined voltage (in order to avoid an indefinite signal at which what voltage value (input value) is expressed is indefinite). In the case of the first exemplary embodiment, as the fixed state, the NC pins are DC connected to the copper tape 190, and are processed so as to be in the directions of outputting signals from the microcomputer 110 with the microcomputer 110 sides being the output sides.

When high frequency plasma is generated within the plasma chamber, an electric field (magnetic field) caused by the high frequency of the power supply for plasma generation is generated within the space of the plasma chamber, and electromotive force is generated at the conductor portions within the plasma chamber. High frequency current flows due to the potential difference of this electromotive force. The potential difference due to the electromotive force arises also in the electronic circuit of DC operation that is set within the plasma. Further, high frequency current flows within the electronic circuit due to this potential difference, but when this current exceeds a given threshold value, the operation of the electronic circuit of DC operation carries out operation in accordance with the high frequency current.

In the first exemplary embodiment, the high frequency electromotive force that is generated in the plasma generation arises at the copper tape 190, and the copper tape 190 and both the positive side and the negative side of the power supplying section 140 of the electronic circuit of DC operation are connected via the capacitors 170a (the positive side), 170b (the negative side). Due thereto, the high frequency electromotive force generated within the electronic circuit of DC operation is forcibly made to be the same potential, and high frequency current, that arises due to the potential difference of the high frequency electromotive force generated due to plasma generation within the electronic circuit of DC operation, does not flow.

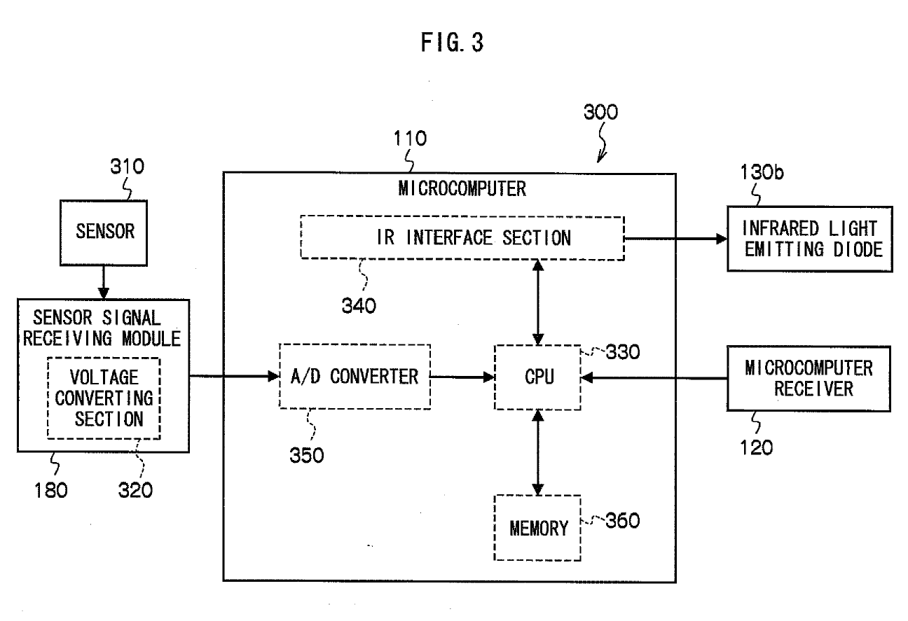

A first block diagram 300 of the microcomputer circuit 100 relating to the first exemplary embodiment is shown in FIG. 3.

The first block diagram 300 is structured by the microcomputer 110, the infrared light emitting diode (infrared LED) 130b, the microcomputer receiving section 120, sensors 310, and a voltage converting section 320 (corresponding to the sensor signal receiving module 180). Further, the microcomputer 110 is structured by a CPU (Central Processing Unit) 330, an IR interface section 340, an A/D converter 350, and the memory 360. Note that there are plural types of the memory 360, that are a ROM (Read Only Memory) in which programs for control for microcomputer control are stored, a RAM (Random Access Memory) in which data is temporarily stored, an NVRAM (Non-Volatile Random Access Memory) that is a non-volatile memory from which data can be read and to which data can be written, an EPROM (Erasable Programmable Read Only Memory) from which data can be deleted and to which data can be written any number of times, and the like.

The sensor signal receiving module 180, that receives the output values (analog values) from the sensors 310 that measure plasma parameters (and are set at respective locations within the semiconductor fabricating device), is connected to the A/D converter 350 for converting into digital signals, via the voltage converting section 320 such as a resistance voltage divider or a transformer or the like. Note that, if the output values from the sensors (the output voltages) are within the range of operational voltages of the microcomputer 110, it suffices to not provide the voltage converting section 320, but there may be the voltage converting section 320 that inputs the output voltages of the signals received at the sensor signal receiving module 180 as are to the A/D converter 350. Further, the plasma parameters include the self bias voltage Vdc and the like, and are, for example, the plasma temperature, the plasma density, the plasma potential, the electric field, the electron density, the electron temperature and the like.

The A/D converter 350 is connected to the CPU 330 in order to perform processing for storing the output values of the A/D converter 350 (digital values) in the memory 360 that is set within the microcomputer 110 (or may be at the exterior of the microcomputer 110).

The memory 360 is connected to the CPU 330.

Further, the IR interface section 340, that is for performing communications with a receiver for reading measured data, is connected to the CPU 330.

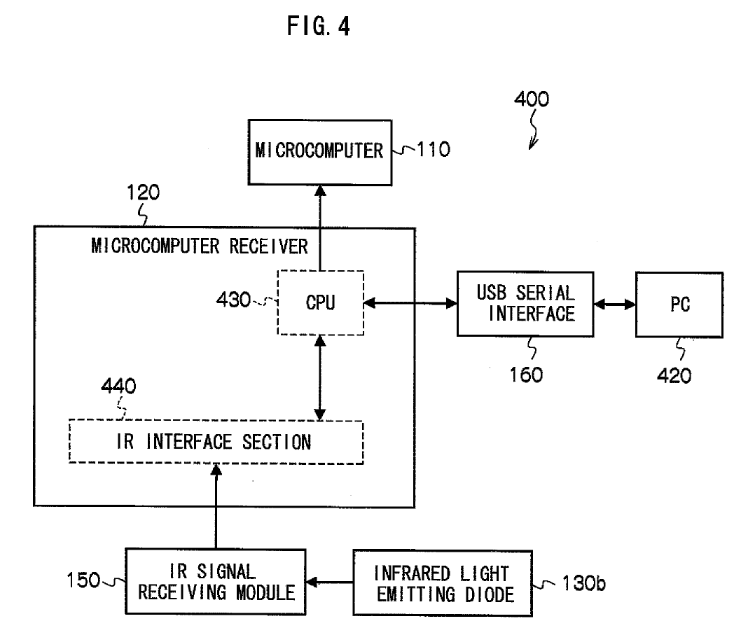

A second block diagram 400 of the microcomputer receiver 120 of the microcomputer 110 relating to the first exemplary embodiment is shown in FIG. 4.

The second block diagram 400 is structured by the microcomputer 110, the microcomputer receiver 120, the IR signal receiving module 150, the infrared light emitting diode (infrared LED) 130b, the USB serial interface 160, and a PC (Personal Computer) 420. Further, the microcomputer receiver 120 is structured by a CPU 430 and an IR interface section 440.

The IR signal receiving module 150 that is needed for IR communications is connected to the microcomputer receiver 120, and the infrared LED 130b and the IR signal receiving module 150 are connected. Further, the microcomputer 110 also is connected to the microcomputer receiver 120. The microcomputer receiver 120 is connected to the USB serial interface 160, and is connected from the USB serial interface 160 via a data transmission cable to the commercially-available PC 420, in order to transfer received data to the commercially-available PC 420. The CPU 430 within the microcomputer receiver 120 is connected to the IR interface section 440 within the microcomputer receiver 120, and to the microcomputer 110 and the USB serial interface. The IR interface section 440 within the microcomputer receiver 120 is connected to the CPU 320 within the microcomputer receiver 120 and to the IR signal receiving module 150.

Operation of the first exemplary embodiment will be described hereinafier.

The sensors 310 are set at respective locations within a semiconductor fabricating device, and have mechanisms that can transmit signals therefrom to the sensor signal receiving module 180. Within the semiconductor fabricating device, the sensors 310 measure, for example, plasma parameters such as the self bias voltage Vdc and the like generated in the plasma processing, as well as the potential of the wafer surface in the plasma processing, the potential generated within the fine pattern, and the like.

First, the sensors 310 transmit the various types of measurement information that are measured (e.g., the plasma parameters such as the self bias voltage Vdc and the like, and the potential of the wafer surface in the plasma processing, and the potential generated within the fine pattern, and the like) to the sensor signal receiving module 180 by using a sensor signal transmitting module that transmits the measurement information from the sensors, or the like. Note that the method of transmission at this time may be transmission by using an LED that emits light of a wavelength different than the wavelength of the infrared LED 130b, or may be transmission by radio (in the case of radio transmission, the sensor signal receiving module is a radio signal receiving module).

The output voltage outputted from the sensor 310 via the sensor signal receiving module 180 is the first measurement value, and passes through the voltage converting section 320 and is boosted or lowered within the range of operational voltage of the microcomputer 110 (if there is no need to boost or lower within the range of operational voltage of the microcomputer 110, the voltage converting section 320 may pass the first measurement value through as is). Thereafter, the first measurement value, that is the output voltage from the sensor 310 that has been boosted or lowered within the range of operational voltage, is, at the A/D converter 350, converted from an analog value (also called the analog voltage value or analog data) into a digital value (also called the digital voltage value or digital data). The converted digital value of the first measurement value is read by a designation register of the CPU 330. Due to the digital value that is read to the CPU 330 being transferred to a designated memory address, the digital value is stored in the memory 360 within the microcomputer 110 (the memory 360 may be set at the exterior of the microcomputer circuit 100).

After the digital value of the first measurement value is stored at the designated memory address of the memory 360 within the microcomputer 110, a digital value of a second measurement value is outputted from the sensor 310 via the A/D converter 350 as a second measurement value that is the next data. The digital value of the second measurement value is read by the designation register of the CPU 330 as an output value. A memory address that is different from the memory address in which the first measurement value is stored is designated, and the digital value, that is the second measurement value read by the designation register of the CPU 330, is transmitted to the memory address of the memory 360 that is designated from the designation register of the CPU 330, and is stored in the designated memory address of the memory 360.

After the digital value of the second measurement value is stored in the memory address of the memory 360, the above-described operations are repeated in order to measure the next third measurement value. The repeating of these operations is carried out until the memory addresses that store data are full, or until the repeated operation is carried out for a pre-designated measurement time period or number of times of measurement. Note that, after the digital value of the first measurement value is stored at a memory address of the memory 360, a given time period may be left free and a delay time period for performing the operation of reading the second measurement value may be generated in order to adjust the measurement cycle.

After measurement of all of the measurement values ends, the microcomputer circuit 100 is taken-out to the exterior of the plasma chamber. Then, the PC 420 and the USB interface 160 are connected, and instruction information for obtaining the measurement information stored in the microcomputer circuit 100 is transmitted from the PC 420 via the USB interface 160 to the CPU 430 of the microcomputer receiver 120. On the basis of the instruction information transmitted from the PC 420, a specific code from the CPU 430 of the microcomputer receiver 120 is transmitted from a wire to the fourth pin 114, and is received by the CPU 330 of the microcomputer 110. The specific code is transmitted from the wire to the fourth pin 114, and when the CPU 330 of the microcomputer 110 recognizes receipt of the specific code, the CPU 330 controls the infrared LED 130b via the IR interface section 340 and carries out IR transmission of all of the measurement values that are the digital values stored in the memory 360. The IR signal receiving module 150 that is connected to the microcomputer receiver 120 receives the signal of the light of the infrared LED 130b, and this signal is transmitted to the CPU 430 via the IR interface section 440 of the microcomputer receiver 120.

Here, the specific code is transmitted from the microcomputer receiver 120 by the wire via the fourth pin 114, but it is also possible to not connect the wire to the fourth pin 114. For example, an infrared LED, whose wavelength is different than that of the infrared LED 130b, may be connected to the microcomputer receiver 120, and an IR signal receiving module for receiving information from the infrared LED whose wavelength is different than that of the infrared LED 130b may be connected to the microcomputer 110, and IR transmission and reception may be carried out between the microcomputer receiver 120 and the microcomputer 110. Or, the infrared LED 130b that is connected to the microcomputer 110 may be connected to the microcomputer receiver 120 as well and used in common, and an IR signal receiving module may be connected to the microcomputer 110 and IR transmission and reception carried out between the both (when either one is using the infrared LED 130b that is used in common, the infrared LED 130b is set so as to not receive signals from the other).

At the microcomputer receiver 120, the measurement values that were transmitted and received from the IR signal receiving module 150 are transferred to the designation register of the CPU 430. After being transferred to the designation register, the measurement values, that were transferred in binary or hexadecimal format, are converted into decimal numbers. After the measurement values that were in binary or hexadecimal format are converted into decimal numbers, they are transferred to a designated output port, and are sent to the commercially-available PC 420 by wire by using the USB cable that is connected to the USB serial interface. The PC 420 displays on a CRT (Cathode Ray Tube) display the measurement values that have been transmitted in, or stores them in an accessory storage device. Note that the PC 420 may store the measurement values, that have been transmitted in, in an accessory storage device while displaying them on a CRT display.

The stored measurement values in decimal format are subjected to general data processing of the PC 420 and are analyzed. For example, for the plasma parameters such as the self bias voltage Vdc and the like generated in the plasma processing, and the potential of the wafer surface in the plasma processing, and the potential generated within the fine pattern, and the like, the trends of in what cases and how these values are changing are displayed on the CRT display of the PC 420 and analyzed.

Further, after all of the data of the measurement values that the microcomputer circuit 100 measured have been transmitted, a specific code of end of transmission is transmitted from the microcomputer circuit 100. The microcomputer receiver 120 recognizes the specific code of end of transmission, and when it recognizes the ending of transmission, stops the receiving operation.

Note that the first exemplary embodiment describes a case in which, after measurement has ended, the microcomputer circuit 100 is taken-out to the exterior of the plasma chamber. However, after measurement ends, gates for wafer transport-in and transport-out may be opened, and for example, the data may be received at the microcomputer receiver 120 that is set within a load lock chamber, and the data of the measurement values may be transmitted to the microcomputer receiver 120 at the exterior by using a data transmitting device or the like. Further, in the first exemplary embodiment, the real-time monitoring device includes the microcomputer circuit 100 that includes the microcomputer 110 and the like, as well as the Kapton tape 210, the sensors 310 and the PC 420.

Accordingly, because the high frequency electromotive force within the microcomputer circuit 100 becomes equal to the high frequency electromotive force that is generated in a vicinity of the microcomputer circuit 100, the dispersion in the high frequency electromotive force generated within the microcomputer circuit 100 can be forcibly made to be the same potential as the high frequency electromotive force in the vicinity of the microcomputer circuit 100.

As a result, flowing of high frequency current due to the potential difference of the high frequency electromotive force does not occur at the microcomputer circuit 100, and therefore, the microcomputer circuit 100 operates only by the potential difference of the DC power supply that is supplied. Thus, the microcomputer 110 can stably perform the operations that are programmed in advance in the memory 36 of the microcomputer 110.

Further, there is no need for covering with a resin material in order to prevent high frequency current, that is due to regular high frequency electromotive force that arises due to a strong high frequency electric field, from intruding into the circuit.

The high frequency electromotive force, that is generated in a vicinity of the microcomputer circuit 100, is generated at the copper tape 190, that is set at the periphery of the vicinity of the microcomputer circuit 100, and is forcibly made to be the same potential as the high frequency electromotive force of the vicinity of the microcomputer circuit 100. Therefore, because the copper tape 190 is connected to the interior of the microcomputer 110 via the power supplying section 140 of the microcomputer 110, there is no need to consider the effects on the setting location due to the amount of the high frequency electromotive force that arises, or the like, and the copper tape 190 can be set at any location of the plasma chamber.

The program that carries out the desired operations at the microcomputer 110 is incorporated in advance in the memory 360, and, due to the microcomputer circuit 100 operating normally, the measurement data from the sensors is digitally processed. Due thereto, the transient state changes from immediately after plasma generation can be accurately measured. In more detail, because the measurement value sampling interval of the program incorporated within the microcomputer circuit 100 can be changed in the program, sudden changes in the transient state immediately after high frequency plasma generation can be measured appropriately.

Moreover, a predetermined program is incorporated in the microcomputer circuit 100, to which is added a structure that causes stable operation in high frequency plasma, and the sensor outputs of the sensors are converted into digital values in accordance with this program. Then, the converted measurement values are stored in the memory 360, and, after measurement ends, the microcomputer circuit 100 is taken-out to the exterior, and the measurement values that are stored in the memory 360 are read-out at the microcomputer receiver 120. The problem relating to the optical path of the light emitting element can thereby be overcome. It is possible to overcome the problem of not being able to observe the light that is the signal, for example, in cases in which there is no observation window at the plasma chamber, or in cases in which, at the time of the wafer processing, the stage on which the wafer is located is moved for the plasma processing and can no longer be viewed from the observation window, or the like.

Because the sensor output values are converted into digital values, signal changes can be grasped more clearly than very weak signal changes by a light emitting element.

When the microcomputer circuit 100 of the first exemplary embodiment is, together with plural optical sensors, built into a semiconductor fabricating device (e.g., an etcher), the light emitting state of the plasma in the wafer processing can be monitored within the plasma generation space. Due thereto, very weak and sudden plasma light emitting changes, such as microarcing and abnormal discharge and the like that are presumed to arise during plasma processing, can be monitored on a wafer-by-wafer basis.

Further, by setting the microcomputer receiver 120 within the load lock chamber, the measurement values acquired by the microcomputer circuit 100 can be transmitted to the microcomputer receiver 120 at the time of wafer transport, and the measurement values received at the microcomputer receiver 120 can be employed as wafer processing data in managing quality.

### Second Exemplary Embodiment

A second exemplary embodiment of the present invention will be described hereinafter.

In the second exemplary embodiment, structures that are the same as the structures described in the first exemplary embodiment are denoted by the same reference numerals, and (description of) these structures is omitted.

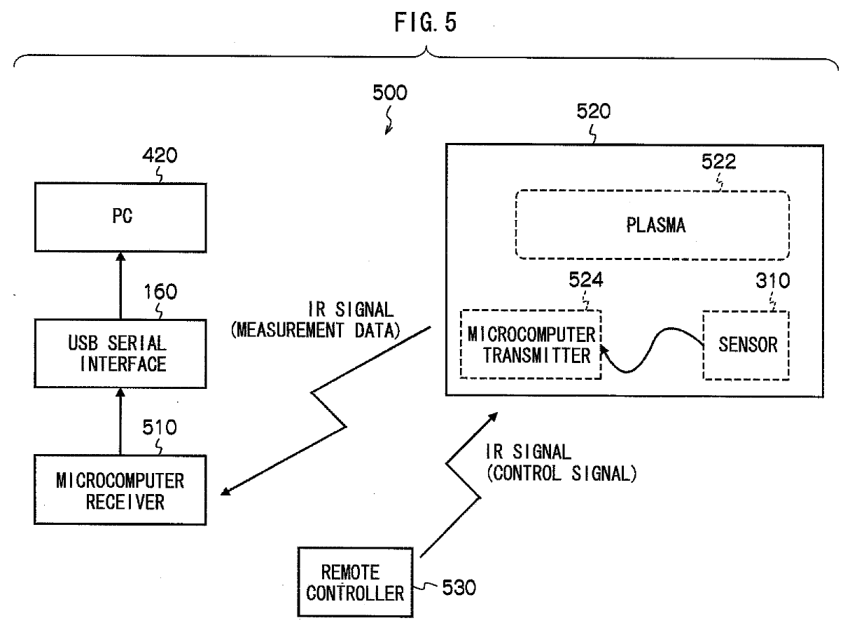

FIG. 5 is a block diagram of a real-time monitoring device 500 relating to a second exemplary embodiment.

The real-time monitoring device 500 is structured by the PC 420, the USB serial interface 160, a microcomputer receiver 510, a semiconductor wafer processing device 520, and a remote controller 530. Further, the sensors 310 that measure at least the plasma parameters including self bias voltage that are observed in the plasma processing within plasma 522, and the potential of the wafer surface in the plasma processing, and the potential generated within the fine pattern, and a microcomputer transmitter 524 (microcomputer circuit) that acquires and stores measurement data that is the sensor outputs measured at the sensors 310, are provided at the semiconductor wafer processing device 520. Note that the semiconductor wafer processing device 520 is, for example, an etching device (an etcher), a CVD (Chemical Vapor Deposition) device, or the like. Further, the plasma parameters include the self bias voltage Vdc and the like, and are, for example, the plasma temperature, the plasma density, the plasma potential, the electric field, the electron density, the electron temperature and the like.

The sensors 310, that are set at respective locations at the interior of the semiconductor wafer processing device 520, and the microcomputer transmitter 524 are connected within the semiconductor wafer processing device 520. Further, the microcomputer receiver 510 is connected to the PC 420 via the USB serial interface 160. The remote controller 530 and the microcomputer receiver 510 perform IR communications with the microcomputer transmitter 524 of the semiconductor wafer processing device 520.

Note that, in the structure of the real-time monitoring device 500 shown in FIG. 5, the microcomputer transmitter 524 that is disposed within the semiconductor wafer processing device 520 is (as a presupposed condition) within an environment that is such that infrared rays are not blocked, so that transmission and reception of IR signals can be carried out by communications (IR communications) by infrared rays with the remote controller 530 and the microcomputer receiver 510. For example, there is an observation window at the semiconductor wafer processing device 520, and a control signal is transmitted from the remote controller 530 by an IR signal, and the microcomputer transmitter 524 that is disposed within the sealed semiconductor wafer processing device 520 receives the control signal. Further, on the basis of the control signal that is an IR signal from the remote controller 530, the microcomputer transmitter 524 carries out transmission of the measurement data stored in the microcomputer transmitter 524 (the measurement data transmitted from the sensors 310), by IR communications to the microcomputer receiver 510. The measurement data, that is transmitted from the microcomputer transmitter 524, is stored once at the microcomputer receiver 510, and is transmitted to the PC 420 via the USB serial interface 160.

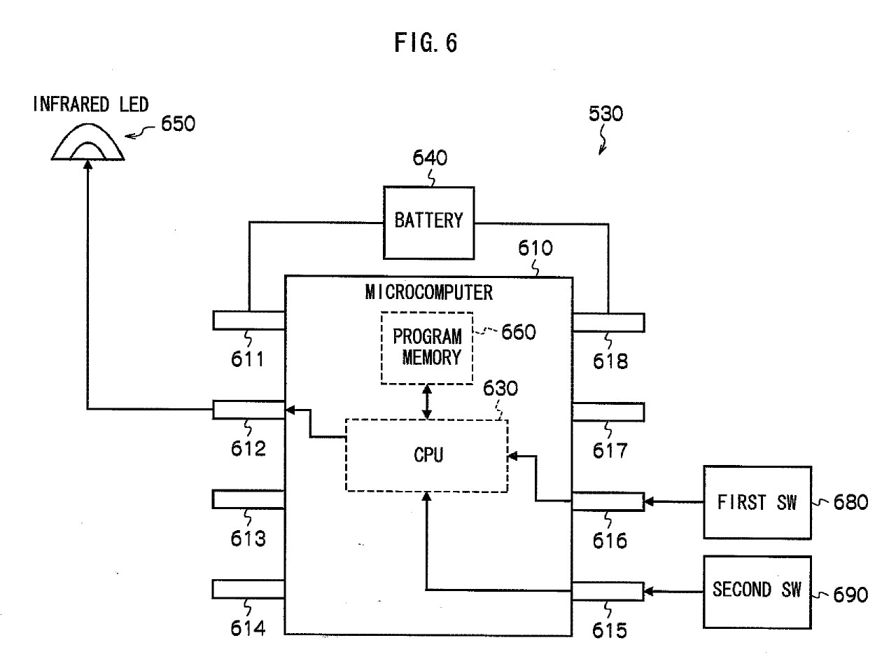

FIG. 6 shows a signal block diagram of the remote controller 530 relating to the second exemplary embodiment.

The signal block diagram of the remote controller 530 is structured by a microcomputer 610, a battery 640, an infrared LED (infrared light emitting diode) 650 that is an infrared ray transmitting unit, a first SW (switch) 680, and a second SW 690. The microcomputer 610 is structured by a CPU 630 and a program memory 660. Further, the microcomputer 610 is an eight-pin-type IC, and has terminals for connection that are a first pin 611, a second pin 612, a third pin 613, a fourth pin 614, a fifth pin 615, a sixth pin 616, a seventh pin 617, and an eighth pin 618.

The battery 640 is connected to the positive side and the negative side of a power supply section of the microcomputer 610 via the first pin 611 and the eighth pin 618, and supplies a power supply to the microcomputer 610. Further, the first SW 680 is connected to the sixth pin 616, and the signal from the first SW 680 is transmitted to the CPU 630. Note that, here, the signal from the first SW 680 is a switch for transmitting to the microcomputer transmitter 524 an IR signal for starting measurement of the measurement data. The second SW 690 is connected to the fifth pin 615, and the signal from the second SW 690 is transmitted to the CPU 630. Note that, here, the signal from the second SW 690 is a switch for causing the microcomputer transmitter 524 to transmit the measurement data to the microcomputer receiver 510. The infrared LED 650 is connected to the second pin 612. On the basis of the signals transmitted from the first SW 680 and the second SW 690, a control signal is transmitted by the CPU 630 via the second pin 612 for IR communications.

Note that the control signal is the IR signal to the microcomputer transmitter 524 for starting measurement of the measurement data, or is the IR signal for causing the microcomputer transmitter 524 to transmit the measurement data to the microcomputer receiver 510.

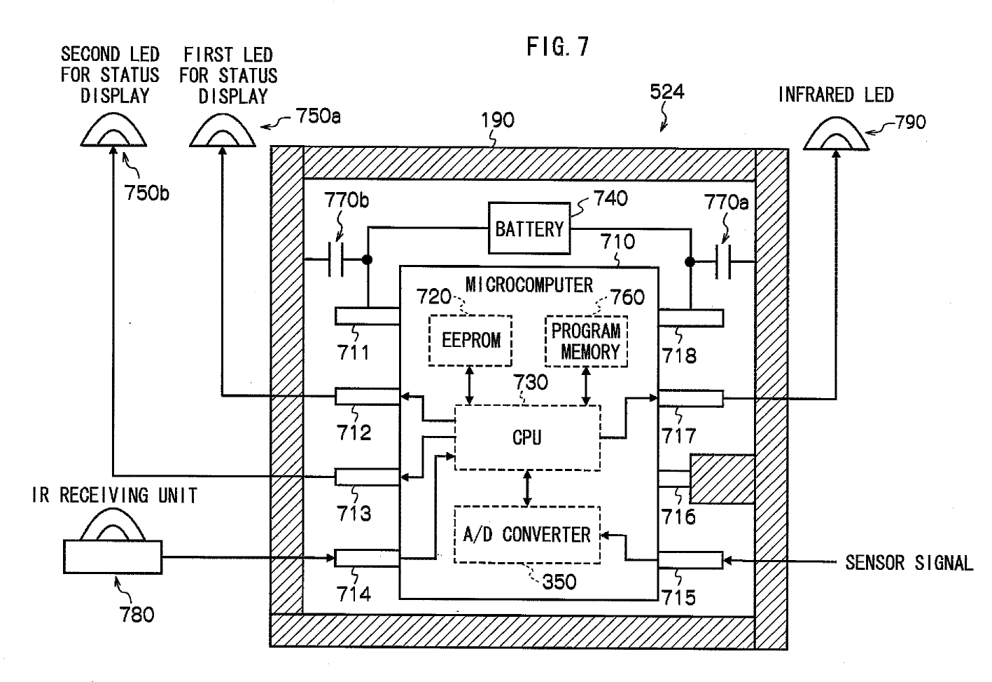

FIG. 7 shows a signal block diagram of the microcomputer transmitter 524 relating to the second exemplary embodiment.

The signal block diagram of the microcomputer transmitter 524 is structured by the copper tape 190, a microcomputer 710, batteries 740, a first LED 750a for status display, a second LED 750b for status display, capacitors 770a, 770b, an IR receiving unit 780, and an infrared LED 790. Further, the microcomputer 710 is structured by an EEPROM (Electronically Erasable and Programmable Read Only Memory) 720, a program memory 760, a CPU 730, and the A/D converter 350. Note that the EEPROM 720 is a ROM (Read Only Memory) whose contents can be rewritten electrically. Further, the microcomputer 710 also is an eight-pin-type IC, and has terminals for connection that are a first pin 711, a second pin 712, a third pin 713, a fourth pin 714, a fifth pin 715, a sixth pin 716, a seventh pin 717, and an eighth pin 718.

The EEPROM 720, the program memory 760, and the A/D converter 350 are respectively connected via the CPU 730. The CPU 730 is connected to the second pin 712, the third pin 713, the fourth pin 714, and the seventh pin 717. The A/D converter 350 is connected to the fifth pin 715 also.

One of the batteries 740 is connected to the first pin 711 by the one capacitor 770a, and the other battery 740 is connected to the eighth pin 718 via the one capacitor 770b. Note that the batteries 740 are connected to the positive side and the negative side of the power supply section of the microcomputer 710 via the first pin 711 and the eighth pin 718, and supply power to the microcomputer 710. Further, the other of the capacitor 770a and the other of the capacitor 770b are connected to the copper tape 190. Note that the sixth pin 716 is an NC pin, and is connected to the copper tape 190. The IR receiving unit 780 is connected to the fourth pin 714, and IR receives a control signal from the remote controller 530 and transmits it to the CPU 730. The first LED 750a for status display is connected to the second pin 712, and receives a status signal from the CPU 730. Similarly to the first LED 750a for status display, the second LED 750b for status display also is connected to the third pin 713, and receives a status signal from the CPU 730. The infrared LED 790 is connected to the seventh pin 717, and receives a signal for transmitting, by IR communications, the measurement data from the CPU 730. The sensors 310 are connected to the A/D converter 350 via the fifth pin 715, and the sensor signals from the sensors 310 are transmitted to the A/D converter 350 via the fifth pin 715.

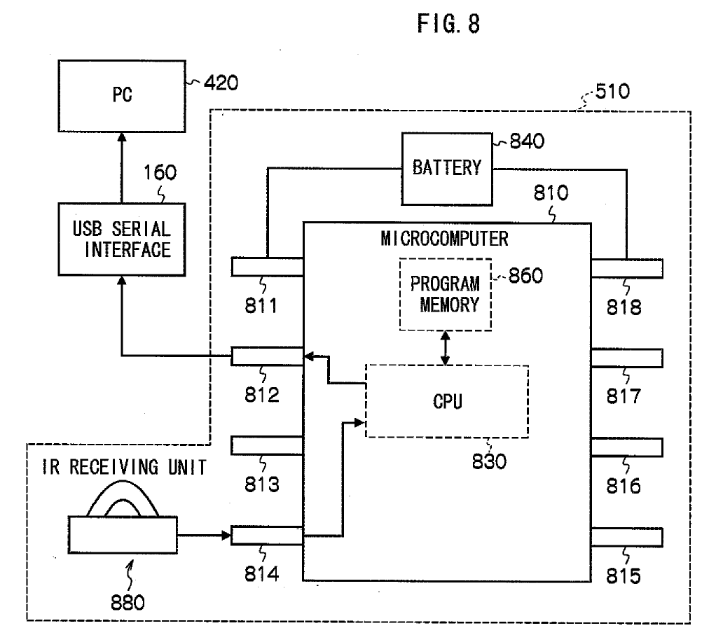

FIG. 8 shows a signal block diagram of the microcomputer receiver 510 relating to the second exemplary embodiment, and the USB interface 160 and the PC 420.

The microcomputer receiver 510 is structured by a microcomputer 810, a battery 840, and an IR receiving unit 880. The microcomputer 810 is structured by a CPU 830 and a program memory 860. Further, the microcomputer 810 is an eight-pin-type IC, and is provided with terminals for connection that are a first pin 811, a second pin 812, a third pin 813, a fourth pin 814, a fifth pin 815, a sixth pin 816, a seventh pin 817 and an eighth pin 818.

The CPU 830 is connected to the program memory 860, the second pin 812, and the fourth pin 814.

The battery 840 is connected to the first pin 811 and the eighth pin 818, and is connected to the positive side and the negative side of the power supply section of the microcomputer 810, and supplies power to the microcomputer 810. The IR receiving unit 880 is connected to the fourth pin 814, and receives measurement data from the microcomputer transmitter 524, and transmits it to the microcomputer 810. The USB serial interface 160 is connected to the second pin 812 and the PC 420, and the measurement data that is transmitted-in from the second pin 812 is transmitted to the PC 420 via the USB interface 160. Note that the third pin 813, the fifth pin 815, the sixth pin 816, and the seventh pin 817 are NC pins.

Operation of the second exemplary embodiment will be described hereinafter.

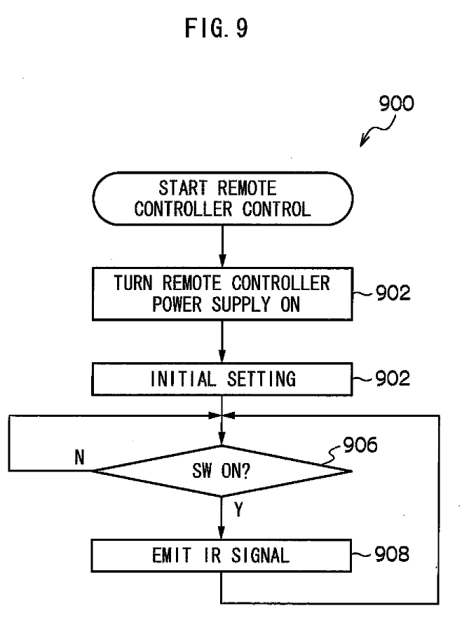

FIG. 9 shows a first flowchart 900 that shows the control of the remote controller 530 relating to the second exemplary embodiment.

In step 902, the power supply of the remote controller 530 is turned on. In more detail, the power supply of the remote controller 530 is turned on at the exterior of the semiconductor wafer processing device 520.

In step 904, initial setting is carried out. In more detail, initialization of the program is carried out, and preparations are carried out for IR transmitting a control signal that is a start signal for measurement of the measurement data to the microcomputer transmitter 524, or a measurement data transmission request signal to transmit the measurement data from the microcomputer transmitter 524 to the microcomputer receiver 510. For example, 0 is clear or is the parameter setting or the like.

In step 906, it is judged whether or not there has been SW input. In more detail, it is judged whether or not the IR signal for measurement start of the measurement data to the microcomputer transmitter 524 has been inputted by the first SW 680, or whether or not the IR signal for causing the microcomputer transmitter 524 to transmit the measurement data to the microcomputer receiver 510 has been inputted by the second SW 690. If the IR signals have been inputted by the first SW 680 and the second SW 690, the routine proceeds to step 908. If the IR signals have not been inputted by the first SW 680 and the second SW 690, step 906 is repeated and the routine stands-by until the SW are on.

In step 908, IR signal emission is carried out. In more detail, if the IR signal has been inputted by the first SW 680, an IR signal to the microcomputer transmitter 524 for starting measurement of the measurement data is emitted. Similarly, if the IR signal has been inputted by the second SW 690, the IR signal for causing the microcomputer transmitter 524 to transmit the measurement data to the microcomputer receiver 510 is emitted.

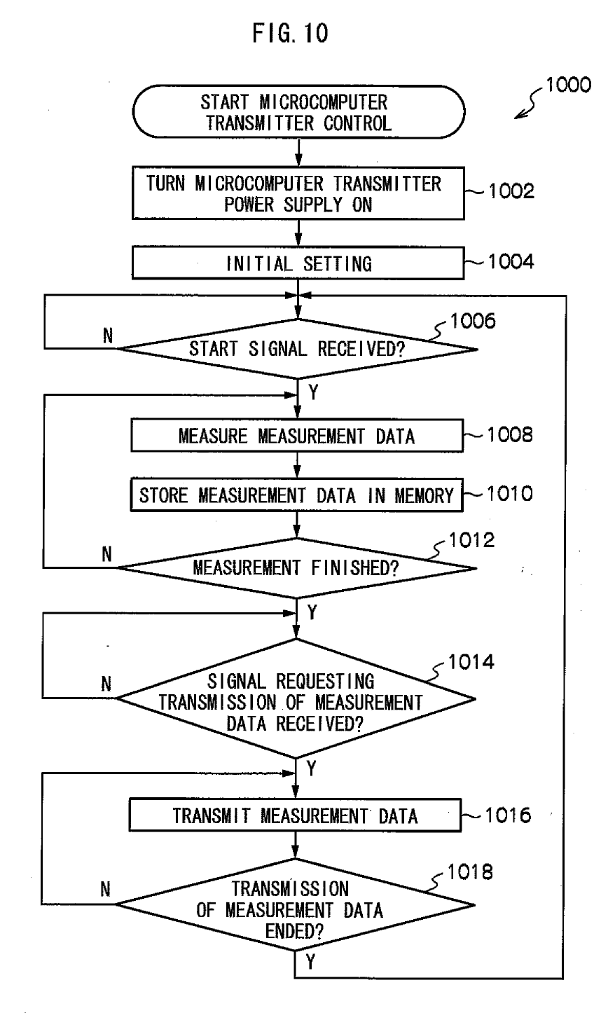

FIG. 10 shows a second flowchart 1000 showing the control of the microcomputer transmitter 524 relating to the second exemplary embodiment.

In step 1002, the power supply of the microcomputer transmitter 524 is turned on. In more detail, the power supply of the microcomputer transmitter 524 is turned on at the exterior of the semiconductor wafer processing device 520, and the microcomputer transmitter 524 is located within the semiconductor wafer processing device 520. Note that the microcomputer transmitter 524 is located on the wafer to be processed on the stage of the semiconductor wafer processing device 520.

In step 1004, initial setting is carried out. In more detail, initialization of the program is carried out, and preparations are carried out so that a start signal for measurement of the measurement data from the remote controller 530 can be received at any time. For example, 0 is clear or is the parameter setting or the like.

In step 1006, it is judged whether or not a start signal has been received. In more detail, it is judged whether or not the IR receiving unit 780 has received an IR signal (the IR signal to the microcomputer transmitter 524 for starting measurement of the measurement data) from the first SW 680 from the remote controller 530, and the control signal for starting acquisition of the measurement data has been received. Note that the IR receiving unit 780 is a unit that receives the control signals that are transmitted in by IR signals from the remote controller 530 (the start signal, or the signal requesting transmission of measurement data), and these control signals are transmitted to the CPU 730 via the fourth pin 714 of the microcomputer 710. If the start signal is received, the routine moves on to step 1008. If the start signal is not received, step 1006 is repeated and the routine stands-by.

In step 1008, the measurement data is measured. In more detail, the CPU 730 that governs control of the microcomputer 710 carries out measurement of the measurement data that is transmitted from the sensors 310, on the basis of the control program stored in the program memory 760. The sensors 310 are disposed at respective locations within the semiconductor wafer processing device 520, and, within the semiconductor wafer processing device 520, measure the measurement data that are, for example, plasma parameters such as the self bias voltage Vdc and the like generated in the plasma processing, and the potential of the wafer surface in the plasma processing, and the potential generated within the fine pattern, and the like. Then, the aforementioned respective types of measurement data that the sensors 310 have measured are transmitted to the microcomputer transmitter 524.

In step 1010, the measurement data is stored in the memory. In more detail, on the basis of the control program stored in the program memory 760, the CPU 730 converts the signal from the sensor 310, that is transmitted in from the fifth pin 715 and is measurement data that is an analog signal, into a digital signal by the A/D converter 350, and stores it in the EEPROM 720. The sensor output (the output voltage) that is outputted from the sensor 310 is a first measurement value, and, via a voltage converting section or the like, is boosted or lowered within the range of operational voltage of the microcomputer transmitter 524 (if there is no need to boost or lower within the range of operational voltage of the microcomputer transmitter 524, the voltage converting section or the like may pass the first measurement value through as is). Thereafter, the first measurement value, that is the output voltage from the sensor 310 that has been boosted or lowered within the range of operational voltage, is, at the A/D converter 350, converted from an analog voltage value into a digital voltage value. The converted digital voltage value of the first measurement value is read by a designation register of the CPU 730. Due to the digital value that is read to the CPU 730 being transferred to a designated memory address, the digital value is stored in the EEPROM 720.

After the digital value of the first measurement value is stored at the designated memory address of the EEPROM 720 within the microcomputer 710, a digital value of a second measurement value is outputted from the sensor 310 via the A/D converter 350 as a second measurement value that is the next data. The digital value of the second measurement value is read as an output value by a designation register of the CPU 730. A memory address that is different from the memory address in which the first measurement value is stored is designated, and the digital value, that is the second measurement value read by the designation register of the CPU 730, is transferred to the memory address of the EEPROM 720 that is designated from the designation register of the CPU 730, and is stored in that designated memory address.

After the digital value of the second measurement value is stored in the memory address of the EEPROM 720, the above-described operations are repeated in order to measure the next third measurement value. The repeating of these operations is carried out until the memory addresses that store data are full, or until the repeated operation is carried out for a pre-designated measurement time period or number of times of measurement. Note that, after the digital value of the first measurement value is stored at a memory address of the EEPROM 720, a given time period may be left free and a delay time period for performing the operation of reading the second measurement value may be generated in order to adjust the measurement cycle.

In step 1012, it is judged whether or not measurement has ended. In more detail, it is judged whether a predetermined number of measurement data have been acquired and stored in the EEPROM 720, or whether measurement data have been stored to the maximum capacity of the EEPROM 720. When measurement ends and a predetermined number of the measurement data are stored in the EEPROM 720 or the measurement data are stored to the maximum capacity of the EEPROM 720, the routine moves on to step 1014. If measurement is not finished, the routine returns to step 1008.

In step 1014, it is judged whether or not a transmission request signal for the measurement data has been received. In more detail, it is judged whether or not the IR signal from the second SW 690 of the remote controller 530 has been received, and the control signal for transmitting the measurement data to the microcomputer receiver 510 (the transmission request signal for the measurement data) has been received. If the transmission request signal for the measurement data has been received, the routine moves on to step 1016. If the transmission request signal for the measurement data has not been received, step 1014 is repeated and the routine stands-by.

In step 1016, transmitting of the measurement data is carried out. In more detail, on the basis of the IR signal from the second SW 690 of the remote controller 530, the measurement data stored in the EEPROM 720 of the microcomputer transmitter 524 is transmitted to the microcomputer receiver 510. Note that the measurement data that is stored in the EEPROM 720 is transmitted from the CPU 730 to the microcomputer receiver 510 via the seventh pin 717 and by an IR signal by the infrared LED 790.

In step 1018, it is judged whether or not transmitting of the measurement data has ended. In more detail, it is judged whether the microcomputer receiver 510 has received all of the measurement data stored in the EPROM 720 of the microcomputer transmitter 524. For example, if the microcomputer receiver 510 has received data expressing the final end data of the measurement data, it is judged that the transmitting of the measurement data has ended. If the microcomputer receiver 510 has not received the data expressing the end data, it is judged that the transmitting of the measurement data has not ended. Further, if the transmitting of the measurement data has ended, the routine returns to step 1006, and preparations for measurement of the next measurement data are carried out. If the transmitting of the measurement data has not ended, the routine returns to step 1016, and the microcomputer receiver 510 repeats reception of the transmitted measurement data.

Note that, at the first LED 750a for status display and the second LED 750b for status display, the situation of the program operating (called the status hereinafter) is known from the way that the LEDs are lit. For example, the first LED 750a for status display and the second LED 750b for status display are LEDs that, by being lit, give notice of the status, such as a case in which an activation signal or a transmission signal or the like has been transmitted in, a case in which the A/D converter or the like is operating, a case in which data is stored in the EEPROM 720, or the like. Further, because it is presumed that the microcomputer transmitter 524 is located on the semiconductor wafer that is undergoing processing within the semiconductor wafer processing device 520, parts whose thicknesses are suppressed to less than or equal to several millimeters (various types of compact LEDS, the compact batteries 740, the compact capacitors 770a, 770b such as chip capacitors, and the microcomputer 710 that has been made compact) are used to achieve compactness.

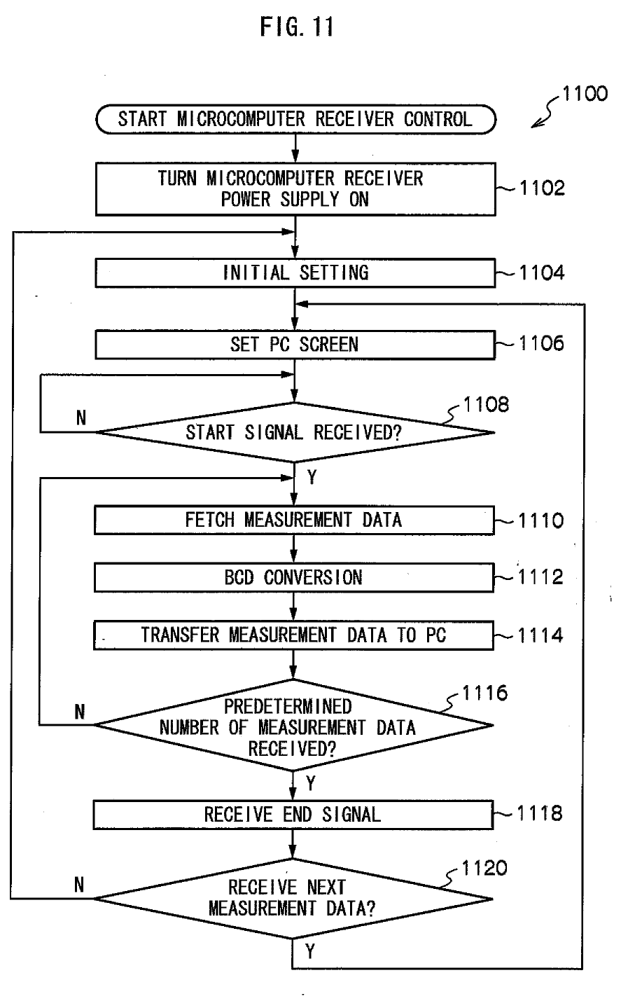

FIG. 11 shows a third flowchart 1100 showing the control of the microcomputer receiver 510 relating to the second exemplary embodiment.

In step 1102, the power supply of the microcomputer receiver 510 is turned on. In more detail, the power supply of the microcomputer receiver 510 is turned on at the exterior of the semiconductor wafer processing device 520.

In step 1104, initial setting is carried out. In more detail, initialization of the program is carried out, and preparations are carried out so that measurement data from the microcomputer transmitter 524 can be received at any time. For example, 0 is clear or is the parameter setting or the like.

In step 1106, screen setting of the PC 420 is carried out. In more detail, the measurement data generated by the program of the microcomputer is read, and setting is carried out to display it on the screen of the PC 420. For example, at the screen of the PC 420, accessory setting of CH (channel) 1, CH2, and the like is carried out, and the data can be displayed as a table by using application software or the like. Note that the PC 420 has only the function of receiving, via the USB serial interface 160, the measurement data that is transmitted to the microcomputer receiver 510 from the microcomputer transmitter 524, and only edits the received measurement data by making it into a table or the like.

In step 1108, it is judged whether or not a start signal has been received. In more detail, it is judged whether or not a start bit has been sensed from the microcomputer transmitter 524. For example, a specific data signal is inserted at the end of the measurement data that is transmitted from the microcomputer transmitter 524, and this signal is sensed, and it is judged whether or not a start bit that is a start signal is sensed.

In step 1110, fetching of the measurement data is carried out. In more detail, if the start signal is received, acquisition of the measurement data that has been transmitted from the microcomputer transmitter 524 is started.

In step 1112, BCD (Binary Coded Decimal) conversion is carried out. In more detail, the measurement data transmitted from the microcomputer transmitter 524 is BCD-converted by the CPU 830, and the measurement data is handled as binary data.

In step 1114, the measurement data is transferred to the PC 420. In more detail, the measurement data, that was BCD-converted and made into binary data in step 1012, is transferred to the PC 420 via the USB serial interface 160.

In step 1116, it is judged whether or not a predetermined number of measurement data have been received. In more detail, it is judged whether or not the microcomputer receiver 510 has received a predetermined number of the measurement data that have been transmitted from the microcomputer transmitter 524 to the microcomputer receiver 510. Note that, rather than judging whether or not the predetermined number of measurement data have been received, it may be judged whether or not measurement data, of the amount of the capacity of the EEPROM 720 that is incorporated in the microcomputer 710 of the microcomputer transmitter 524, have been received.

In step 1118, an end signal is received. In more detail, an end signal, that expresses that the measurement data transmitted from the microcomputer transmitter 524 to the microcomputer receiver 510 is the final data, is received.

In step 1120, it is judged whether or not receipt of the next measurement data is to be carried out. In more detail, after receipt of the end signal in step 1118, it is judged whether or not reception of the next measurement data is to be carried out. If reception of the next measurement data is to be carried out, the routine moves on to step 1106, and screen setting of the PC 420 is carried out. If reception of the next measurement data is not to be carried out, the routine returns to the initial setting of step 1104, and stands-by until measurement data is acquired.

Note that, at the PC 420, the measurement values that are transmitted may be displayed-on the CRT display, or may be stored in an accessory storage device. Further, the measurement values that are stored are subjected to general data processing of the PC 420, and are analyzed. For example, for the plasma parameters such as the self bias voltage Vdc and the like generated in the plasma processing, and the potential of the wafer surface in the plasma processing, and the potential generated within the fine pattern, and the like, the trends of in what cases and how these values are changing within the semiconductor wafer processing device 520 are displayed on the CRT display of the PC 420 by using application software or the like, and are analyzed.

Accordingly, in the second exemplary embodiment, because the high frequency electromotive force within the microcomputer 710 becomes equal to the high frequency electromotive force that is generated in a vicinity of the microcomputer 710, the dispersion in the high frequency electromotive force generated within the microcomputer 710 can forcibly be made to be the same potential as the high frequency electromotive force of the vicinity of the microcomputer 710.

As a result, flowing of high frequency current due to the potential difference of the high frequency electromotive force does not occur at the microcomputer 710, and therefore, the microcomputer 710 operates only by the potential difference of the DC power supply that is supplied. Thus, the microcomputer 710 can stably perform the operations that are programmed in advance in the program memory 760.

Further, there is no need for covering with a resin material in order to prevent the high frequency current, that is due to regular high frequency electromotive force that arises due to a strong high frequency electric field, from intruding into the circuit.

The high frequency electromotive force, that is generated in a vicinity of the microcomputer 710, is generated at the copper tape 190 that is set at the periphery of the vicinity of the microcomputer 710, and is forcibly made to be the same potential as the high frequency electromotive force of the vicinity of the microcomputer 710. Therefore, because the copper tape 190 is connected to the interior of the microcomputer 710 via the power supplying section 740 of the microcomputer 710, there is no need to consider the effects on the setting location due to the amount of the high frequency electromotive force that arises, or the like, and the microcomputer transmitter 524 including the microcomputer 710 can be set at any location of the semiconductor wafer processing device 520. Because the microcomputer transmitter 524 that includes the microcomputer 710 also can be made to be small, it also can be located in the gap of several millimeters above the slice that is being processed by the semiconductor wafer processing device 520.

Because the measurement value sampling interval of the program incorporated in the program memory 760 of the microcomputer 710 can be changed in the program, sudden changes in the transient state immediately after high frequency plasma generation can be measured appropriately.

Because the sensor output values are converted into digital values, signal changes can be grasped more clearly than very weak signal changes by a light emitting element.

When the microcomputer 710 of the second exemplary embodiment is, together with plural optical sensors, built into the semiconductor wafer processing device 520, the light emitting state of the plasma during the wafer processing can be monitored within the plasma generation space. Due thereto, very weak and sudden plasma light emitting changes, such as microarcing and abnormal discharge and the like that are presumed to arise during plasma processing, can be monitored on a wafer-by-wafer basis.

Further, by setting the microcomputer receiver 510 within the load lock chamber, the measurement values acquired by the microcomputer 610 can be transmitted to the microcomputer receiver 510 at the time of wafer transport, and the measurement values received at the microcomputer receiver 510 can be employed as wafer processing data in managing quality.

As described above, in accordance with the present invention, plasma parameters from immediately after plasma generation, or output data of a sensor that measures the potential of a processed wafer surface, can be stably collected and stored in a memory and transferred to the exterior of a plasma chamber.

What is claimed is:

1. A real-time monitoring device comprising:
a microcomputer that monitors changes during plasma processing in a potential of a semiconductor wafer surface that are read by a sensor;
a conductor disposed in a vicinity of the microcomputer; and
a capacitor that connects the conductor and a power supply connection terminal of the microcomputer.

2. A real-time monitoring device according to claim 1, wherein:
the microcomputer collects sensor outputs of sensors that are disposed at respective locations within a semiconductor fabricating device, and in a plasma process used in a semiconductor fabricating process, senses and measures at least one of plasma parameters including self bias voltage, a potential of a plasma processed wafer surface, or a potential generated within a fine pattern, and the microcomputer is part of a microcomputer circuit that controls a monitoring operation of sensor outputs in the plasma process; and
the conductor is disposed in a vicinity of a circuit whose main body is the microcomputer and that comprises a plurality of electronic parts.

3. The real-time monitoring device according to claim 1, wherein, when there is an unused terminal at the microcomputer, the unused terminal and the conductor are directly connected, or the unused terminal is connected to a negative power supply side via a resistor.

4. The real-time monitoring device according to claim 2, wherein, when there is an unused terminal at the microcomputer, the unused terminal and the conductor are directly connected, or the unused terminal is connected to a negative power supply side via a resistor.

5. A real-time monitoring device comprising:
a microcomputer that monitors changes during plasma processing in a potential of a semiconductor wafer surface that are read by a sensor,
wherein a connecting portion of a direct current power supply that is supplied to the microcomputer has a potential equal to a high frequency voltage induced by plasma.

6. The real-time monitoring device according to claim 5, wherein, when there is an unused terminal at the microcomputer, the unused terminal is directly connected to a conductor, or is connected to a negative power supply portion via a resistor.

7. The real-time monitoring device according to claim 5, wherein a conductor is disposed in a vicinity of the microcomputer, and a capacitor is connected between the conductor and a power supply connection terminal of the microcomputer, and a connecting portion of a direct current power supply that is supplied to the microcomputer has a potential equal to a high frequency voltage induced by plasma.

8. A real-time monitoring device according to claim 5, wherein:
the microcomputer collects sensor outputs of sensors that are disposed at respective locations within a semiconductor fabricating device, and in a plasma process used in a semiconductor fabricating process, senses and measures at least one of plasma parameters including self bias voltage, a potential of a plasma processed wafer surface, or a potential generated within a fine pattern; and
a conductor is disposed in a vicinity of a circuit whose main body is the microcomputer and that comprises a plurality of electronic parts, and the connecting portion of a direct current power supply supplied to the microcomputer is connected by a capacitor to the conductor, the microcomputer being part of a microcomputer circuit that controls a monitoring operation of sensor outputs in the plasma process, and the conductor having a potential equal to a high frequency voltage induced by plasma, when there is an unused terminal at the microcomputer, the unused terminal is directly connected to the conductor or is connected to a negative power supply portion via a resistor, and
operationally unstable signal transmitting and receiving operations caused by a high frequency electric field of the microcomputer circuit are stabilized.

9. A control method for measuring a potential used in a microcomputer circuit in a real-time monitoring device,
the real-time monitoring device comprising:
a microcomputer that collects sensor outputs of sensors that are disposed at respective locations within a semiconductor fabricating device and that, in a plasma process used in a semiconductor fabricating process, sense and measure at least one of plasma parameters including self bias voltage, a potential of a plasma processed wafer surface, or a potential generated within a fine pattern; and
a conductor disposed in a vicinity of a circuit whose main body is the microcomputer and that comprises a plurality of electronic parts,
where the conductor and a power supply connection terminal of the microcomputer are connected via a capacitor, the microcomputer being part of a microcomputer circuit that controls a monitoring operation of sensor outputs in the plasma process,
the method comprising:
inputting the sensor outputs;
performing AD conversion that converts the sensor outputs from analog signals into digital signals;
storing measurement data corresponding to digital signals of the AD-converted sensor outputs; and
in accordance with a specific signal, performing IR transmission that transmits, by infrared rays, the stored measurement data.

10. The real-time monitoring device according to claim 2, wherein
the microcomputer circuit comprises a power supply section, a capacitor, an infrared ray receiving unit, and an infrared ray transmitting unit, and
the real-time monitoring device further comprises:
a control signal transmitting section that transmits a control signal generated by infrared rays for controlling the microcomputer circuit, such that the control signal is received by the infrared ray receiving unit;
a sensor output receiving section that receives the sensor outputs from the infrared ray transmitting unit of the microcomputer circuit; and
an analyzing section that analyzes the sensor outputs received by the sensor output receiving section.

11. The real-time monitoring device according to claim 3, wherein
the microcomputer circuit comprises a power supply section, a capacitor, an infrared ray receiving unit, and an infrared ray transmitting unit, and
the real-time monitoring device further comprises:
a control signal transmitting section that transmits a control signal generated by infrared rays for controlling the microcomputer circuit, such that the control signal is received by the infrared ray receiving unit;
a sensor output receiving section that receives the sensor outputs from the infrared ray transmitting unit of the microcomputer circuit; and
an analyzing section that analyzes the sensor outputs received by the sensor output receiving section.

12. A real-time monitoring device according to claim 2, further comprising:
a power supply section, an infrared ray receiving unit, and an infrared ray transmitting unit;
a control signal transmitting section that transmits a control signal generated by infrared rays for controlling the microcomputer circuit, such that the control signal is received by the infrared ray receiving unit;
a sensor output receiving section that receives, from the infrared ray receiving unit, the sensor outputs from the infrared ray transmitting unit of the microcomputer circuit; and
an analyzing section that analyzes the sensor outputs received by the sensor output receiving section,
wherein, on the basis of the control signal from the control signal transmitting section, the microcomputer circuit acquires the sensor outputs, and stores the acquired sensor outputs temporarily in a sensor output storing section, and, on the basis of the control signal from the control signal transmitting section, the microcomputer circuit transmits the sensor outputs by using the infrared ray transmitting unit.

13. The real-time monitoring device according to claim 12, wherein, when there is an unused terminal at the microcomputer, the unused terminal and the conductor are directly connected, or the unused terminal is connected to a negative power supply section via a resistor.

14. A real-time monitoring device according to claim 2,
wherein the microcomputer circuit comprises:
an inputting section that inputs the sensor outputs;
an AD converting section that performs AD conversion that converts the sensor outputs inputted by the inputting section from analog signals into digital signals;
a storing section that stores measurement data corresponding to digital signals of the AD-converted sensor outputs by the AD converting section;
an IR transmitting section that performs, in accordance with a specific signal, IR transmission that transmits, by infrared rays, the stored measurement data; and
a control section that controls the inputting section, the AD converting section, the storing section and the IR transmitting section,
the control section that executes the AD conversion, the storing of the AD-converted measurement data, and, in response to the specific signal, the IR transmission of the stored measurement data.
